(19) United States
(12) Patent Application Publication
(10) Pub. No.: US 2015/0162480 A1
(43) Pub. Date: Jun. 11, 2015

(54) METHOD OF MANUFACTURING CI(G)S-BASED THIN FILM HAVING REDUCED CARBON LAYER, THIN FILM MANUFACTURED BY THE METHOD, AND SOLAR CELL COMPRISING THE THIN FILM

(71) Applicant: KOREA INSTITUTE OF ENERGY RESEARCH, Daejeon (KR)

(72) Inventors: Ara Cho, Daejeon (KR); Kyung Hoon Yoon, Daejeon (KR); SeJin Ahn, Daejeon (KR); Jae Ho Yun, Daejeon (KR); Jihye Gwak, Daejeon (KR); Joo Hyung Park, Daejeon (KR); Jin Su Yoo, Seoul (KR); Jun Sik Cho, Daejeon (KR); Seoungkyu Ahn, Daejeon (KR); Young Joo Eo, Daejeon (KR); Kihwan Kim, Daejeon (KR)

(21) Appl. No.: 14/418,071

(22) PCT Filed: Aug. 9, 2013
(86) PCT No.: PCT/KR2013/007195

§ 371 Date: Jan. 28, 2015

(30) Foreign Application Priority Data
Aug. 10, 2012 (KR) 10-2012-0087925

(51) Int. Cl. H01L 31/18; H01L 31/0392; H01L 31/032

(52) U.S. Cl. CPC H01L 31/18; H01L 31/0322; H01L 31/03923

(57) ABSTRACT

Disclosed is a method of manufacturing a CI(G)S-based thin film, in which a slurry prepared by mixing two or more kinds of binary nanoparticles containing CI(G)S-based elements, a solution precursor containing a CI(G)S-based element, an alcoholic solvent and a chelating agent is used to reduce the carbon layer formed between the CI(G)S-based thin film and molybdenum, and which includes (a) mixing two or more kinds of binary nanoparticles containing CI(G)S-based elements, a solution precursor containing a CI(G)S-based element, an alcoholic solvent and a chelating agent, thus preparing a slurry; (b) subjecting the slurry to non-vacuum coating, thus forming a CI(G)S-based thin film; and (c) subjecting the CI(G)S-based thin film to selenization heat treatment.

### TECHNICAL FIELD

The present invention relates to a method of manufacturing a CI(G)S-based thin film using binary nanoparticles, a thin film manufactured by the method and a solar cell comprising the thin film. More particularly, the present invention relates to a method of manufacturing a CI(G)S-based thin film, a thin film manufactured by the method and a solar cell comprising the thin film, wherein a slurry obtained by mixing two or more kinds of binary nanoparticles containing CI(G)S-based elements, a solution precursor containing a CI(G)S-based element, an alcoholic solvent and a chelating agent is used to reduce the carbon layer formed between a CI(G)S-based thin film and molybdenum.

### BACKGROUND ART

Due to present serious environmental pollution problems and pending fossil energy exhaustion, the importance for the development of next-generation clean energy is increasing. In particular, solar cells are a device for directly converting solar energy into electric energy, and are expected to be an energy source able to solve future energy problems because they produce low pollution, operate on the unlimited resource of sunlight and have a semi-permanent lifetime.

Solar cells are variously classified depending on the type of material used for the light absorption layer thereof. Currently mainly useful is a silicon solar cell using silicon. However, as the price for silicon solar cells has drastically increased due to the short supply of silicon, thin film-type solar cells are receiving a great attention. A thin film-type solar cell is manufactured to be slim, and thus has a wide application range because of low material consumption and light weight. Thorough research is ongoing into amorphous silicon and CdTe, CIS or CIGS as materials for thin film-type solar cells.

CIS or CIGS thin films are compound semiconductors that exhibit the highest conversion efficiency (20.3%) among thin film solar cells made in lab. Such CIS or CIGS thin films may be manufactured to a thickness of 10 μm or less and may manifest stable properties even upon long-term use, making it possible to achieve an inexpensive high-efficiency solar cell that can replace silicon. Furthermore, a CIS thin film, which is a direct transition semiconductor, may be provided in the form of a thin film and is comparatively adapted for light conversion because it has a bandgap of 1.04 eV, and the coefficient of light absorption thereof is high among known solar cell materials. A CIGS thin film is developed by substituting a portion of In with Ga or by substituting S with Se to improve low open voltage of the CIS thin film.

A CIGS-based solar cell is manufactured in the form of a thin film having a thickness corresponding to ones of μm, and the manufacturing method thereof largely includes a vacuum deposition process, and a non-vacuum process including applying a precursor material and then performing heat treatment. Specifically, a vacuum deposition process is advantageous because an absorption layer having high efficiency may be manufactured, but it is difficult to uniformly form a large-area absorption layer and expensive equipment has to be used, and furthermore, 20˜50% of the material used may be lost, undesirably increasing the manufacturing cost. On the other hand, a non-vacuum coating process including applying a precursor material and then performing high-temperature heat treatment may exhibit low manufacturing cost and enables a large-area layer to be uniformly formed, but the efficiency of the absorption layer is comparatively low. In particular, a thin film obtained by a solution process using only a solution precursor is problematic because of low absorption efficiency due to the thick carbon layer formed between the CI(G)S-based thin film and molybdenum.

Korean Patent Application Publication No. 10-2010-0048043 discloses a method of manufacturing a CIGS thin film using a non-vacuum coating process, but is undesirable in terms of requiring use of a toxic solvent such as hydrazine.

### DISCLOSURE

### Technical Problem

Accordingly, the present invention has been made keeping in mind the above problems encountered in the related art regarding formation of CI(G)S-based thin films by a conventional solution process using only a CI(G)S-based solution precursor, and the present invention is intended to provide a method of manufacturing a CI(G)S-based thin film having a reduced carbon layer, wherein a hybrid slurry obtained by mixing two or more kinds of binary nanoparticles containing CI(G)S-based elements, a solution precursor containing a CI(G)S-based element, an alcoholic solvent and a chelating agent may be used to reduce the carbon layer formed between the CI(G)S-based thin film and molybdenum, ultimately improving solar cell efficiency.

In addition, the present invention is intended to provide a method of manufacturing a CI(G)S-based thin film, which enables a CI(G)S-based thin film to be more eco-friendly and stably manufactured without the need for a toxic solvent such as hydrazine that has been essentially used in conventional methods.

### Technical Solution

The present invention provides a method of manufacturing a CI(G)S-based thin film, comprising: (a) mixing two or more kinds of binary nanoparticles containing CI(G)S-based elements, a solution precursor containing a CI(G)S-based element, an alcoholic solvent and a chelating agent, thus preparing a slurry; (b) subjecting the slurry to non-vacuum coating, thus forming a CI(G)S-based thin film; and (c) subjecting the CI(G)S-based thin film to selenization heat treatment.

The two or more kinds of binary nanoparticles may be prepared by any one selected from among a low-temperature colloidal process, a solvothermal synthesis process, a microwave process and an ultrasonic synthesis process.

The two or more kinds of binary nanoparticles may comprise a combination of two or more of binary nanoparticles selected from the group consisting of Cu—S, Cu—Se, In—Se, In—S, Ga—Se and Ga—S, and may particularly comprise any one combination selected from the group consisting of (Cu—S nanoparticles, In—Se nanoparticles), (Cu—S nanoparticles, Ga— Se nanoparticles) and (Cu—S nanoparticles, In—Se nanoparticles, Ga—Se nanoparticles).

The solution precursor containing the CI(G)S-based element may be indium acetate or gallium acetylacetonate.

The alcoholic solvent may be any one selected from the group consisting of ethanol, methanol, pentanol, propanol and butanol.

The chelating agent may be any one selected from the group consisting of monoethanolamine (MEA), diethanolamine (DEA), triethanolamine (TEA), ethylenediamine, ethylenediamine acetic acid (EDTA), nitrilotriacetic acid (NTA), hydroxyethylenediamine triacetic acid (HEDTA), glycol-bis(2-aminoethylether)-N,N,N′,N′-tetraacetic acid (GEDTA), triethylenetetramine hexaacetic acid (TTHA), hydroxyethylimino diacetic acid (HIDA) and dihydroxyethylglycine (DHEG).

In the method of the present invention, (a) may further comprise performing ultrasonication so that slurry components are mixed and dispersed.

In the method of the present invention, (b) may be performed using any one non-vacuum coating process selected from among a spraying process, an ultrasonic spraying process, a spin coating process, a doctor blading process, a screen printing process and an inkjet printing process.

In the method of the present invention, (b) may further comprise performing drying, after coating.

As such, coating and drying in (b) may be sequentially repeated and performed a plurality of times.

In the method of the present invention, (c) may be performed in such a manner that heat treatment is carried out while supplying a selenium vapor at a substrate temperature of 500˜530° C. for 60˜90 min.

In addition, the present invention provides a CI(G)S-based thin film for use in a light absorption layer of a solar cell, wherein the CI(G)S-based thin film is formed by applying a slurry comprising two or more kinds of binary nanoparticles containing CI(G)S-based elements, a solution precursor containing a CI(G)S-based element, an alcoholic solvent and a chelating agent.

In addition, the present invention provides a solar cell comprising a CI(G)S-based thin film as a light absorption layer, wherein the CI(G)S-based thin film is formed by applying a slurry comprising two or more kinds of binary nanoparticles containing CI(G)S-based elements, a solution precursor containing a CI(G)S-based element, an alcoholic solvent and a chelating agent.

### Advantageous Effects

According to the present invention, hybrid ink is manufactured using two or more kinds of binary nanoparticles and then applied, and thereby a material remaining after reaction can be discharged through pores between particles, thus forming a CI(G)S-based thin film having a comparatively thin carbon layer. When the carbon layer is reduced in this way, the efficiency of a solar cell including such a CI(G)S-based thin film can be improved.

### DESCRIPTION OF DRAWINGS

FIG. 1 illustrates a scanning electron microscope (SEM) image of the surface of a CIS thin film manufactured in Example 1;

FIG. 2 illustrates an SEM image of the surface of a CIS thin film manufactured in Comparative Example 1;

FIG. 3 illustrates a graph of elemental analysis of the CIS thin film manufactured in Example 1;

FIG. 4 illustrates a graph of elemental analysis of the CIS thin film manufactured in Comparative Example 1;

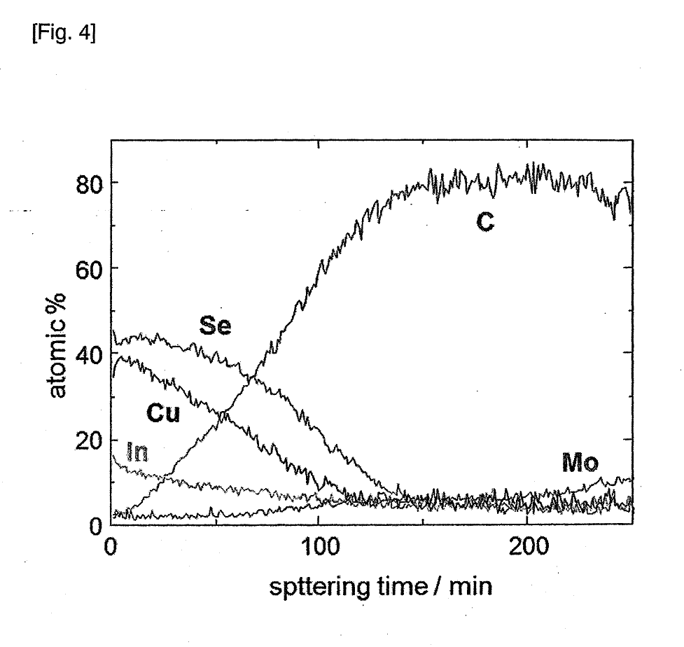

FIG. 5 illustrates an efficiency curve of a solar cell including the CIS thin film of Example 1; and

FIG. 6 illustrates an efficiency curve of a solar cell including the CIS thin film of Comparative Example 1.

### MODE FOR INVENTION

Hereinafter, a detailed description will be given of the present invention.

The present invention addresses a method of manufacturing a CI(G)S-based thin film, comprising: mixing two or more kinds of binary nanoparticles containing CI(G)S-based elements, a solution precursor containing a CI(G)S-based element, an alcoholic solvent and a chelating agent, thus preparing a slurry (Step a); subjecting the slurry to non-vacuum coating, thus forming a CI(G)S-based thin film (Step b); and subjecting the CI(G)S-based thin film to selenization heat treatment (Step c).

Step a is a process of preparing a slurry that is a precursor of a CI(G)S-based thin film. The slurry may be prepared by mixing two or more kinds of binary nanoparticles containing CI(G)S-based elements, a solution precursor containing a CI(G)S-based element, an alcoholic solvent and a chelating agent.

As such, the CI(G)S-based thin film refers to a CIS or CIGS thin film. Also, the CI(G)S-based element refers to any one or a combination of two or more selected from among elements such as Cu, In, Ga, S and Se.

In order to reduce the carbon layer upon preparation of the CIS- or CIGS-based thin film according to the present invention, two or more kinds of binary nanoparticles containing CI(G)S-based elements have to be essentially used. This is because the material remaining after reaction may be discharged through pores between such nanoparticles, and thus the carbon layer, which is closely related to solar cell efficiency, may be reduced. When a single kind of binary particle is used, a desired effect of reducing the carbon layer cannot be obtained.

Two or more kinds of binary nanoparticles containing CI(G)S-based elements refer to all combinations resulting from reacting any one element of Cu, In and Ga with any one element of S and Se. Examples thereof may include combinations of two or more of binary nanoparticles selected from the group consisting of Cu—S, Cu—Se, In—Se, In—S, Ga—Se and Ga—S. Preferably useful is any one combination selected from the group consisting of (Cu—S nanoparticles, In—Se nanoparticles), (Cu—S nanoparticles, Ga—Se nanoparticles) and (Cu—S nanoparticles, In—Se nanoparticles, Ga—Se nanoparticles). The Cu—S nanoparticles may be CuS or Cu₂₋ₓS (0<x<1) nanoparticles; the In—Se nanoparticles may be In₂Se₃ nanoparticles; the In—S nanoparticles may be InS or In₂S₃; Cu—Se may be CuSe, Cu₂Se or Cu₂₋ₓSe (0<x<1); Ga—S may be Ga₂S₃; and Ga—Se may be Ga₂Se₃.

Such binary nanoparticles may be prepared using a process known in the art to which the present invention belongs, such as a low-temperature colloidal process, a solvothermal synthesis process, a microwave process or an ultrasonic synthesis process.

In Step a, the slurry further includes a solution precursor containing a CI(G)S-based element, in addition to two or more kinds of binary nanoparticles. The solution precursor containing a CI(G)S-based element is an acetate, acetylacetonate or halide of a CI(G)S-based element, and is preferably indium acetate or gallium acetylacetonate. Accordingly, the hybrid slurry including the nanoparticles and the solution precursor is prepared, and may contain particles for decreasing series resistance of the carbon layer while lowering the thickness of the carbon layer that is subsequently formed, thereby improving solar cell efficiency. Furthermore, the solution precursor is used to supply an additional element necessary for a CIS or CIGS thin film and also to make the thin film dense.

In Step a, the slurry includes a solvent, that is, an alcoholic solvent. The alcoholic solvent is not toxic and may be easily obtained at low price, compared to hydrazine. Preferably useful is any one selected from the group consisting of ethanol, methanol, pentanol, propanol and butanol.

In Step a, the slurry essentially includes a binder, that is, a chelating agent. The chelating agent according to the present invention functions to bind binary nanoparticles, for example, Cu—S nanoparticles and In—Se nanoparticles, and also to aid bonding with the solution precursor that may be additionally used. Furthermore, it makes the prepared thin film dense and smooth. Such a chelating agent is preferably any one selected from the group consisting of monoethanolamine (MEA), diethanolamine (DEA), triethanolamine (TEA), ethylenediamine, ethylenediamine acetic acid (EDTA), nitrilotriacetic acid (NTA), hydroxyethylenediamine triacetic acid (HEDTA), glycol-bis(2-aminoethylether)-N,N,N′,N′-tetraacetic acid (GEDTA), triethylenetetramine hexaacetic acid (TTHA), hydroxyethylimino diacetic acid (HIDA) and dihydroxyethylglycine (DHEG). Taking into consideration chemical bonding of the solution precursor, the amount of the chelating agent may be determined based on the molar ratio of the solution precursor. Particularly, the molar ratio of solution precursor to chelating agent may be set to 1:6˜20.

Also, Step a may further include performing sonication so that the slurry components are mixed and dispersed. Such sonication enables formation of a more uniform thin film via uniform mixing and dispersion of the slurry components.

Subsequently, the slurry prepared in Step a is formed into a CI(G)S-based thin film via non-vacuum coating (Step b).

The CI(G)S-based thin film is formed by non-vacuum coating. Non-vacuum coating is carried out using a spraying process, an ultrasonic spraying process, a spin coating process, a doctor blading process, a screen printing process or an inkjet printing process as well-known in the art. The use of such a non-vacuum coating process may reduce the manufacturing cost.

When the solvent is used, Step b may further include drying after the coating process. Preferably, three-step drying is performed on a hot plate, for example, at 80˜100° C. upon first drying, 110˜150° C. upon second drying and 200˜280° C. upon third drying, so that the solvent may be effectively removed. The drying time may be appropriately selected.

Also, coating and drying procedures in Step b may be sequentially repeated and performed a plurality of times, giving a thin film having a desired thickness. As such, the number of repeated procedures may vary as necessary, but may be set to 2 or 3.

Finally, the formed CI(G)S-based thin film is subjected to selenization heat treatment (Step c).

Selenization heat treatment, which is essential in a non-vacuum coating process, may be performed in such a manner that the temperature of the substrate having the thin film thereon is increased while supplying a selenium vapor formed by evaporating a selenium solid by heat. Thereby, the precursor thin film formed in Step d is selenized, and simultaneously, the structure in the thin film is finally made dense, thus completing a CI(G)S-based thin film. Preferably, heat treatment is carried out while supplying the selenium vapor at a substrate temperature of 500˜530° C. for 60˜90 min.

In addition, the present invention addresses a CI(G)S-based thin film manufactured by the method as above.

In addition, the present invention addresses a solar cell including the CI(G)S-based thin film as a light absorption layer.

Below is a description of exemplary embodiments of the present invention.

### Preparative Example 1

### Synthesis of Cu—S Binary Nanoparticles

In a glove box, 7.618 g of CuI was mixed with 60 ml of a distilled pyridine solvent, and the resulting mixture was mixed with 3.1216 g of Na₂S dissolved in 40 ml of distilled methanol. As such, the atomic ratio of Cu to S was 1:1. Thereafter, while the methanol/pyridine mixture was mechanically stirred in an ice bath at 0° C., it was allowed to react for 7 min, thus synthesizing a colloid including Cu—S nanoparticles. The colloid was centrifuged at 10000 rpm for about 10 min, sonicated for 1 min and then washed with distilled methanol. These procedures were repeated to completely remove byproducts and pyridine from the product, yielding Cu—S binary nanoparticles having high purity.

### Preparative Example 2

### Synthesis of In—Se Binary Nanoparticles

In a glove box, 4.9553 g of InI₃ was mixed with 30 ml of a distilled tetrahydrofuran solvent, and the resulting mixture was mixed with 1.874 g of Na₂Se dissolved in 20 ml of distilled methanol. As such, the atomic ratio of In to Se was 2:3. Thereafter, while the methanol/pyridine mixture was mechanically stirred in an ice bath at 0° C., it was allowed to react for 7 min, thus synthesizing a colloid including In—Se nanoparticles. The colloid was centrifuged at 10000 rpm for about 10 min, sonicated for 1 min and then washed with distilled methanol. These procedures were repeated to completely remove byproducts and pyridine from the product, yielding In—Se binary nanoparticles having high purity.

### Preparative Example 3

### Synthesis of Ga—Se Binary Nanoparticles

In a glove box, 4.5044 g of GaI₃ was mixed with 30 ml of a distilled tetrahydrofuran solvent, and the resulting mixture was mixed with 1.874 g of Na₂Se dissolved in 20 ml of distilled methanol. As such, the atomic ratio of Ga to Se was 2:3. Thereafter, while the methanol/pyridine mixture was mechanically stirred in an ice bath at 0° C., it was allowed to react for 7 min, thus synthesizing a colloid including Ga—Se nanoparticles. The colloid was centrifuged at 10000 rpm for about 10 min, sonicated for 1 min and then washed with distilled methanol. These procedures were repeated to completely remove byproducts and pyridine from the product, yielding Ga—Se binary nanoparticles having high purity.

### Example 1

### Manufacture of CIS Thin Film

0.41 g of the Cu—S binary nanoparticles of Preparative Example 1, 0.47 g of the In—Se binary nanoparticles of Preparative Example 2, 0.24 g of indium acetate, 0.83 g of monoethanolamine and 2.9 g of a methanol solvent were mixed, and then sonicated for 60 min, thus preparing a CIS-based slurry. As such, the atomic ratio of Cu—S binary nanoparticles to In—Se binary nanoparticles was maintained at 1:1, the molar ratio of In—Se binary nanoparticles to indium acetate was 1:0.5, and the molar ratio of indium acetate to chelating agent was maintained at 1:15. The amount of added methanol was adjusted so as to be adapted for viscosity, thus preparing a slurry.

Thereafter, the prepared slurry was applied via spin coating on a sodalime glass substrate having a No thin film deposited thereon. The rotational speed of the glass substrate was 800 rpm, and the rotational time was set to 20 sec. After the coating process, three-step drying was performed on a hot plate. Specifically, first drying at 80° C. for 5 min, second drying at 120° C. for 5 min and third drying at 200° C. for 5 min were carried out. Such coating and drying procedures were repeated three times, thereby forming a precursor thin film having a thickness of about 2 μm.

Finally, selenization heat treatment was performed for 60 min while supplying Se vapor at a substrate temperature of 530° C., yielding a CIS thin film.

### Example 2

### Manufacture of CIGS Thin Film

0.21 g of the Cu—S binary nanoparticles of Preparative Example 1, 0.12 g of the In—Se binary nanoparticles of Preparative Example 2, 0.10 g of the Ga—Se binary nanoparticles of Preparative Example 3, 0.08 g of indium acetate, 0.32 g of monoethanolamine and 2.60 g of a methanol solvent were mixed, and then sonicated for 60 min, thus preparing a CIGS-based slurry. As such, the atomic ratio of Cu—S binary nanoparticles to In—Se binary nanoparticles to Ga—Se binary nanoparticles was maintained at 5:1:1, the molar ratio of In—Se binary nanoparticles to indium acetate was 1:1, and the molar ratio of indium acetate to chelating agent was maintained at 1:19. The amount of added methanol was adjusted so as to be adapted for viscosity, thus preparing a slurry.

Thereafter, the prepared slurry was applied via spin coating on a sodalime glass substrate having a Mo thin film deposited thereon. The rotational speed of the glass substrate was 800 rpm, and the rotational time was set to 20 sec. After the coating process, three-step drying was performed on a hot plate. Specifically, first drying at 80° C. for 5 min, second drying at 120° C. for 5 min and third drying at 200° C. for 5 min were carried out. Such coating and drying procedures were repeated three times, thereby forming a precursor thin film having a thickness of about 2 μm.

Finally, selenization heat treatment was performed for 60 min while supplying Se vapor at a substrate temperature of 530° C., yielding a CIGS thin film.

### Comparative Example 1

A solution mixture comprising a copper acetate precursor solution, an indium acetate precursor solution and methanol was prepared. Coating and drying procedures of the solution mixture were repeated three times in the same manner as in Example 1, after which selenization heat treatment was conducted under the same conditions as in Example 1.

Comparison of Surface Properties of CIS Thin Films

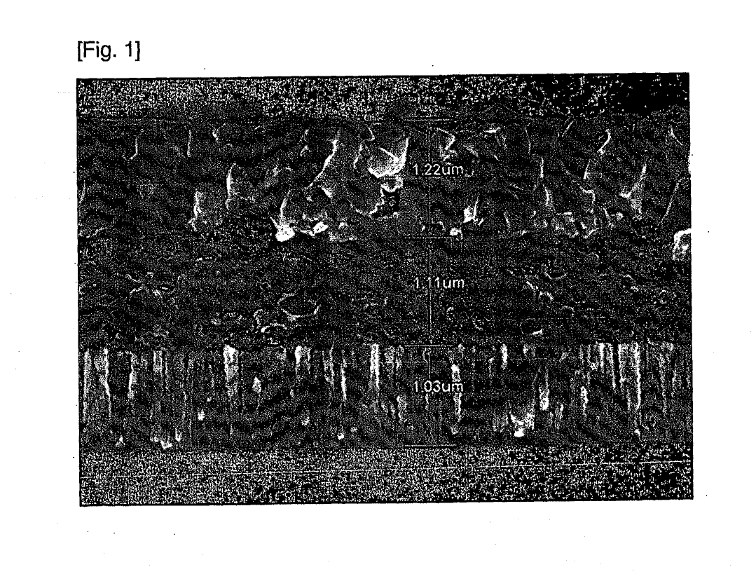

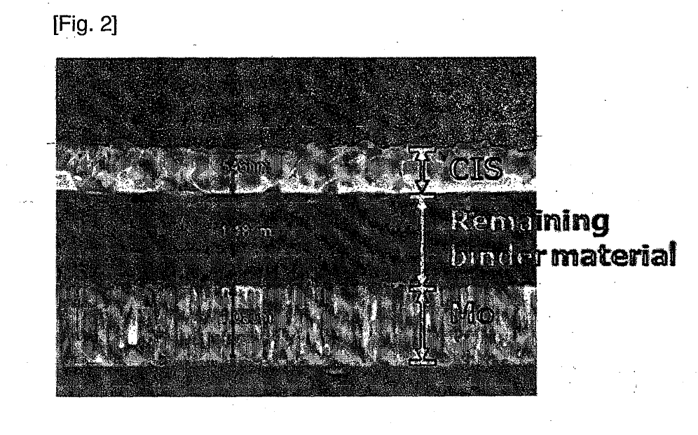

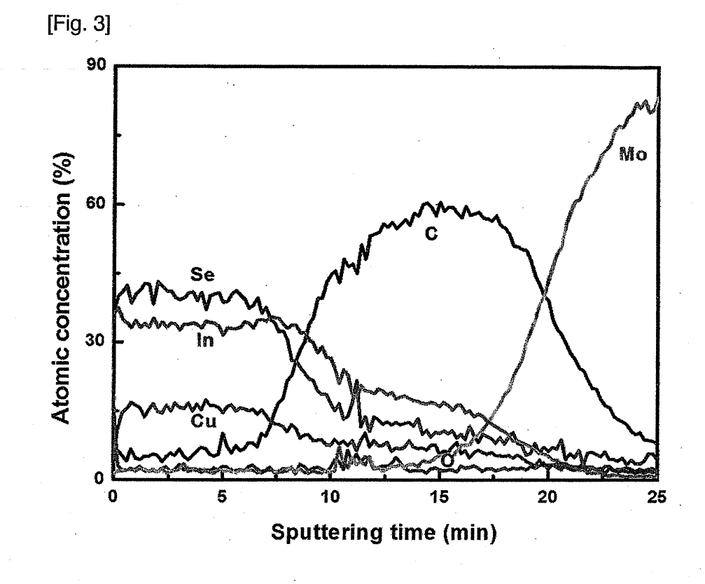

As illustrated in FIGS. 1 and 2, the thin film of Comparative Example 1 was composed of a carbon layer and a CIS thin film layer at a ratio of 2:1, in which the carbon layer was formed to be considerably thick. However, the thin film of Example 1 was configured such that the carbon layer and the CIS thin film were formed at a ratio of 1:1, in which the carbon layer was reduced. Also, as illustrated in FIGS. 3 and 3, the surface of the thin film of Comparative Example 1 was formed with CISe, and Cu, In and Se elements were seldom present in the thick carbon layer and only carbon having high resistance was present therein. The surface of the thin film of Example 1 was formed with CISe, and Cu, In and Se elements were contained in the carbon layer. This means that the thin film according to the present invention aids movement of electric current toward the Mo electrode to thus prevent the cell efficiency from decreasing.

Measurement and Comparison of Solar Cell Efficiencies

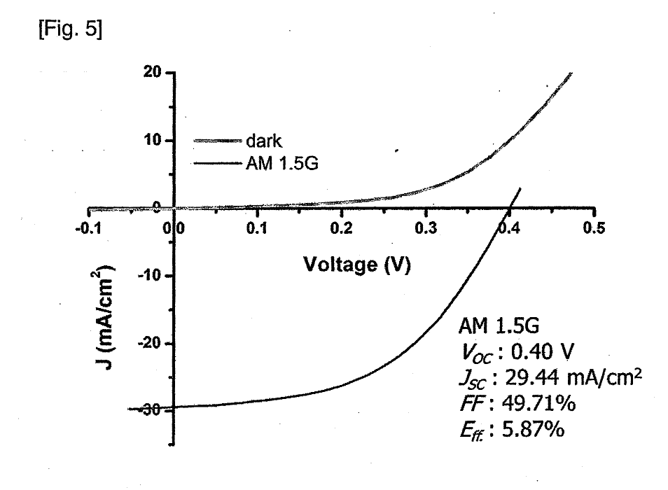

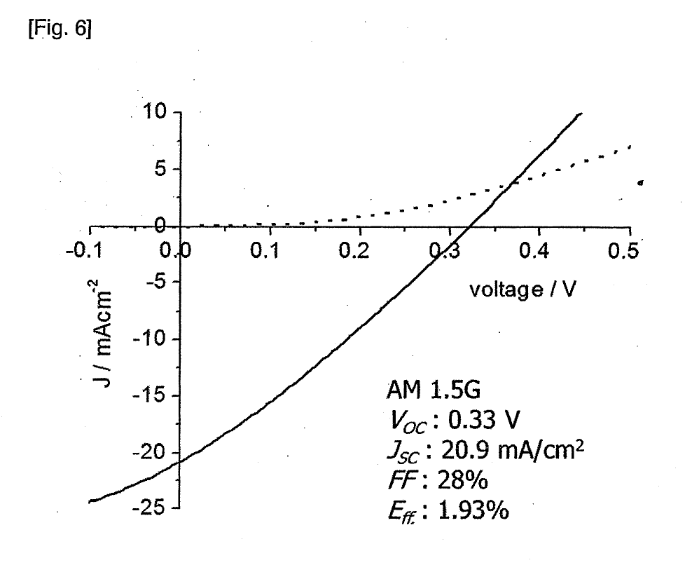

The efficiencies of the solar cells were measured and compared. The efficiency curves of the solar cells are shown in FIG. 5 (Example 1) and FIG. 6 (Comparative Example 1). As illustrated in FIGS. 5 and 6, the solar cell including the thin film according to the present invention is configured such that the carbon layer is reduced and excess nanoparticles are present in the carbon layer, and thereby the cell efficiency is increased from 1.93% to 5.87%.

1. A method of manufacturing a CI(G)S-based thin film, comprising:
(a) mixing two or more kinds of binary nanoparticles containing CI(G)S-based elements, a solution precursor containing a CI(G)S-based element, an alcoholic solvent and a chelating agent, thus preparing a slurry;
(b) subjecting the slurry to non-vacuum coating, thus forming a CI(G)S-based thin film; and
(c) subjecting the CI(G)S-based thin film to selenization heat treatment.

2. The method of claim 1, wherein the two or more kinds of binary nanoparticles comprise a combination of two or more of binary nanoparticles selected from the group consisting of Cu—S, Cu—Se, In—Se, In—S, Ga—Se and Ga—S.

3. The method of claim 1, wherein the two or more kinds of binary nanoparticles comprise any one combination selected from the group consisting of (Cu—S nanoparticles, In—Se nanoparticles), (Cu—S nanoparticles, Ga—Se nanoparticles) and (Cu—S nanoparticles, In—Se nanoparticles, Ga—Se nanoparticles).

4. The method of claim 1, wherein the binary nanoparticles are prepared by any one selected from among a low-temperature colloidal process, a solvothermal synthesis process, a microwave process and an ultrasonic synthesis process.

5. The method of claim 1, wherein the solution precursor containing the CI(G)S-based element is indium acetate or gallium acetylacetonate.

6. The method of claim 1, wherein the alcoholic solvent is any one selected from the group consisting of ethanol, methanol, pentanol, propanol and butanol.

7. The method of claim 1, wherein the chelating agent is any one selected from the group consisting of monoethanolamine (MEA), diethanolamine (DEA), triethanolamine (TEA), ethylenediamine, ethylenediamine acetic acid (EDTA), nitrilotriacetic acid (NTA), hydroxyethylenediamine triacetic acid (HEDTA), glycol-bis(2-aminoethylether)-N,N,N′,N′-tetraacetic acid (GEDTA), triethylenetetramine hexaacetic acid (TTHA), hydroxyethylimino diacetic acid (HIDA) and dihydroxyethylglycine (DHEG).

8. The method of claim 1, wherein (a) further comprises performing ultrasonication so that slurry components are mixed and dispersed.

9. The method of claim 1, wherein (b) is performed using any one non-vacuum coating process selected from among a spraying process, an ultrasonic spraying process, a spin coating process, a doctor blading process, a screen printing process and an inkjet printing process.

10. The method of claim 1, wherein (b) further comprises performing drying, after coating.

11. The method of claim 1, wherein coating and drying in (b) are sequentially repeated and performed a plurality of times.

12. The method of claim 1, wherein (c) is performed in such a manner that heat treatment is carried out while supplying a selenium vapor at a substrate temperature of 500˜530° C. for 60˜90 min.

13. A CI(G)S-based thin film for use in a light absorption layer of a solar cell, wherein the CI(G)S-based thin film is manufactured by mixing two or more kinds of binary nanoparticles containing CI(G)S-based elements, a solution precursor containing a CI(G)S-based element, an alcoholic solvent and a chelating agent, thus preparing a slurry, subjecting the slurry to non-vacuum coating, thus forming a CI(G)S-based thin film, and subjecting the CI(G)S-based thin film to selenization heat treatment.

14. A solar cell comprising a CI(G)S-based thin film as a light absorption layer, wherein the CI(G)S-based thin film is manufactured by mixing two or more kinds of binary nanoparticles containing CI(G)S-based elements, a solution precursor containing a CI(G)S-based element, an alcoholic solvent and a chelating agent, thus preparing a slurry, subjecting the slurry to non-vacuum coating, thus forming a CI(G)S-based thin film, and subjecting the CI(G)S-based thin film to selenization heat treatment.
